(19) United States
(12) Patent Application Publication
(10) Pub. No.: US 2024/0133980 A1
(43) Pub. Date: Apr. 25, 2024

(54) DEVICE FOR DETECTING A MAGNETIC FIELD AND SYSTEM OF MAGNETIC FIELD MEASUREMENT COMPRISING SUCH A DEVICE

(71) Applicant: Commissariat à l'Energie Atomique et aux Energies Alternatives, Paris (FR)

(72) Inventor: Jean-Pierre NIKOLOVSKI, Grenoble (FR)

(21) Appl. No.: 18/489,080

(22) Filed: Oct. 17, 2023

(30) Foreign Application Priority Data
Oct. 20, 2022 (FR) 2210915

(51) Int. Cl. G01R 33/038; G01H 11/08; G01R 33/028

(52) U.S. Cl. CPC G01R 33/0385; G01H 11/08; G01R 33/028

(57) ABSTRACT

The present description relates to a device (20) for detecting a magnetic field (B_{z}) comprising a first tapered acoustic waveguide (40) having a first base (41) and a first tapered end (42), a first electrically conductive wire (50) rigidly coupled to the first tapered end (42), and an electroacoustic transducer (60) rigidly coupled to the first base (41).

### FIELD

The present description relates generally to the measurement of static or time-varying magnetic fields.

### BACKGROUND

For some applications, it would be desirable to be able to measure a static or time-varying magnetic field with a spatial resolution of less than 0.1 mm. In addition, for some applications, it would be desirable to be able to measure a time-varying magnetic field, in particular a pulsed or high-frequency magnetic field. In addition, for some applications, it would be desirable to be able to measure a low-intensity or high-intensity magnetic field with the same device.

An example of a commercially available device for detecting a magnetic is a Hall-effect sensor. However, such a sensor generally has a spatial accuracy of more than 0.1 mm and is therefore unsuitable for measuring a highly localized magnetic field. In addition, existing Hall-effect sensors have a limited bandwidth of no more than 100 kHz, and are therefore unsuitable for measuring a high-frequency magnetic field. In addition, existing Hall-effect sensors cannot be driven synchronously with a magnetic pulse source, and are therefore unsuitable for measuring a pulsed magnetic field.

### SUMMARY

One embodiment addresses some or all of the drawbacks of known devices for detecting a magnetic field and magnetic field measurement systems comprising such devices.

An object of one embodiment is that the device for detecting a magnetic field enables measurement of a static or time-varying magnetic field with a spatial resolution of less than 0.2 mm.

An object of one embodiment is that the device for detecting a magnetic field measures a magnetic pulse.

An object of one embodiment is that the device for detecting a magnetic field can be manufactured at reduced cost.

One embodiment provides a device for detecting a magnetic field comprising:
a first tapered acoustic waveguide having a first base and a first tapered end;
a first electrically conductive wire rigidly coupled to the first tapered end; and
an electroacoustic transducer rigidly coupled to the first base.

According to one embodiment, the first tapered acoustic waveguide extends along an axis from the first base to the first tapered end, the cross-section of the first tapered acoustic waveguide decreasing from the first base to the first tapered end, and the first electrically conductive wire comprises a portion orthogonal to said axis at the first tapered end.

According to one embodiment, the electroacoustic transducer is an electroacoustic transducer with transverse waves polarized perpendicular to the plane defined by the axis of the first tapered acoustic waveguide and the tangent to the first electrically conductive wire when orthogonal to the axis at the first tapered end, and which propagate in the first base-first tapered end direction.

According to one embodiment, the first tapered acoustic waveguide is shaped like a cone or truncated cone.

According to one embodiment, the first tapered acoustic waveguide has an apex angle of less than 15°.

According to one embodiment, the first tapered acoustic waveguide is shaped like a truncated cone, with the first tapered end comprising a flat surface.

According to one embodiment, the flat surface has a diameter less than or equal to half a wavelength of the phase velocity of the bending waves in the first tapered end.

According to one embodiment, the flat surface has a radius of less than 1 mm.

According to one embodiment, the first tapered acoustic waveguide comprises a notch in the flat surface receiving the first electrically conductive wire.

According to one embodiment, the first tapered acoustic waveguide is shaped like a prism with a triangular base.

According to one embodiment, the first electrically conductive wire comprises an electrically conductive track deposited on the first tapered acoustic waveguide.

According to one embodiment, the first electrically conductive wire comprises an electrically conductive blade extending along a flank of the first tapered acoustic waveguide away from said flank and connected to the first tapered end.

According to one embodiment, the electroacoustic transducer is a piezoelectric transverse wave transducer or an electromagnetic transverse wave transducer.

According to one embodiment, the first tapered acoustic waveguide is made of a non-magnetic material.

According to one embodiment, the first tapered acoustic waveguide is made of a material selected from the group comprising glass, silicon, ceramics, non-magnetic metals, austenitic steel and non-magnetic metal alloys.

According to one embodiment, the melting temperature of the first tapered acoustic waveguide and the melting temperature of the first electrically conductive wire are above 1000° C.

According to one embodiment, the device comprises a support of electrically insulating material surrounding the first tapered acoustic waveguide midway between the first base and the first tapered end.

According to one embodiment, the device comprises an electrically conductive shell surrounding the first tapered acoustic waveguide, at a distance from the tapered acoustic waveguide, and comprising an opening for the passage of the first tapered end.

According to one embodiment, the electroacoustic transducer comprises a second tapered acoustic waveguide comprising a second base and a second tapered end, a second electrically conductive wire rigidly coupled to the second tapered end, and a first permanent magnet facing the second tapered end.

According to one embodiment, the first tapered acoustic waveguide and the second tapered acoustic waveguide form a single piece.

According to one embodiment, the device further comprises a third tapered acoustic waveguide rigidly coupled to the first tapered acoustic waveguide, the third tapered acoustic waveguide comprising a third base and a third tapered end, a third electrically conductive wire rigidly coupled to the third tapered end, and a second permanent magnet opposite the third tapered end, the electroacoustic transducer being located between the first base and the third base.

According to one embodiment, the electroacoustic transducer comprises two opposing piezoelectric plates operating in phase opposition.

One embodiment also provides a magnetic field measurement system comprising a device for detecting a magnetic field as defined above, and a control and acquisition device connected to the device for detecting a magnetic field comprising a generator configured to supply at least one current pulse in the first electrically conductive wire and an acquisition chain for detecting an electrical signal supplied by the electroacoustic transducer or a generator configured to supply at least one voltage pulse controlling the electroacoustic transducer and an acquisition chain for detecting an electrical signal supplied by the first electrically conductive wire.

According to one embodiment, the magnetic field corresponds to a magnetic pulse, and the control and acquisition device is configured so that the generator provides a current pulse in the first conductor wire that is electrically synchronous with the magnetic pulse.

According to one embodiment, the control and acquisition device comprises a generator control module configured to receive a binary synchronization signal and a signal representative of a delay and to control the generator to supply the current pulse or the voltage pulse at the end of the delay after reception of the synchronization signal.

According to one embodiment, the generator is configured to supply the current pulse with a duration twice as short as the period corresponding to the frequency of maximum variation of the magnetic field.

According to one embodiment, the control and acquisition device comprises an amplifier receiving the measurement signal, the gain of which is programmable in increasing steps, each step corresponding to a possible range of variation in the magnitude of the magnetic field to be measured.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a schematic, partial cross-sectional view of an embodiment of a system for detecting a magnetic field;

FIG. 2, FIG. 3, FIG. 4, FIG. 5, FIG. 6, and FIG. 7 are schematic, partial cross-sectional views of other embodiments of the probe of the detection system;

FIG. 8 and FIG. 9 are block diagrams of the detection system shown in FIG. 1, illustrating different embodiments of the control and acquisition device of the detection system;

FIG. 10 is a schematic, partial cross-sectional view of an embodiment of a transducer of the probe of the system for detecting a magnetic field;

FIG. 11 is a schematic, partial cross-sectional view of an alternative embodiment of the probe 20 shown in FIG. 10;

FIG. 12 is a schematic, partial top view of a further embodiment of a system for detecting a magnetic field;

FIG. 13 is a schematic, partial side view of the probe of the system for detecting a magnetic field shown in FIG. 12;

FIG. 14 is a schematic, partial top view of a variant of the probe shown in FIG. 12;

FIG. 15 is a schematic, partial top view of an alternative embodiment of the probe and electroacoustic transducer of the system for detecting a magnetic field shown in FIG. 12;

FIG. 16 is a schematic, partial top view of an alternative embodiment of the probe and electroacoustic transducer of the system for detecting a magnetic field shown in FIG. 12;

FIG. 17 is a schematic, partial top view of another embodiment of a system for detecting a magnetic field;

FIG. 18 is a schematic, partial side view of the probe of the system for detecting a magnetic field shown in FIG. 17;

FIG. 19 is a schematic, partial top view of a further embodiment of a system for detecting a magnetic field;

FIG. 20 is a schematic, partial side view of the probe of the system for detecting a magnetic field shown in FIG. 19; and

FIG. 21, FIG. 22, FIG. 23, FIG. 24, FIG. 25 and FIG. 26 illustrate curves evolution as a function over time of the measurement signal supplied by the system for detecting a magnetic field, obtained during tests.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures, or to a probe as orientated during normal use.

Unless specified otherwise, the expressions “around”, “approximately”, “substantially” and “in the order of” signify within 10%, and preferably within 5%. In the case of angles, the expressions “about”, “approximately”, “substantially” and “of the order of” mean to within 10°, preferably to within 5°. Furthermore, the terms “insulating” and “conductive” are taken here to mean “electrically insulating” and “electrically conductive” respectively.

FIG. 1 is a schematic, partial cross-sectional view of a system 10 for detecting a

component B_{z} of a magnetic field \vec{B}.

The system 10 comprises a device for detecting a magnetic field 20, hereinafter referred to as the probe, and a control and acquisition device 30 connected to the probe 20. Probe 20 comprises an acoustic waveguide 40, an electrically conductive wire 50, and an electroacoustic transducer 60.

Acoustic waveguide 40 has a tapered shape along an axis D, having a cross-section the surface of which decreases from a base 41 to a tapered end 42, hereinafter referred to as the tip, opposite the base 41. Acoustic waveguide 40 is hereinafter referred to as tapered guide 40. Conductor wire 50 extends along side wall 43 of tapered guide 40 to tip 42. According to one embodiment, the conductor wire 50 is folded over the tip 42 and secured to the tip 42 by a bonding material 70.

According to one embodiment, the tapered guide 40 has the general shape of a cone or truncated cone. Preferably, the tapered guide 40 is rotationally symmetrical about the axis D. According to another embodiment, the tapered guide 40 has a generally prismatic shape, in particular with a triangular base. At least in a plane containing the axis D, the tapered guide 40 has a triangular cross-section with an apex angle α of less than 15°, preferably less than 10°, more preferably less than 5°. When the tapered guide 40 has the general shape of a cone or truncated cone, the apex angle α corresponds to the angle at the apex of the cone. When the tapered guide 40 has the general shape of a prism with a triangular base, the angle at the apex α corresponds to the angle at the apex of the triangular base on the side of the tip 42 of the tapered guide 40. The conductor wire 50 has a portion 52 covering the tapered guide tip 40, in which the current flows substantially perpendicular to the axis D of the tapered guide 40.

In operation, the tip 42 of the tapered guide 40 is positioned where the magnetic field \vec{B} is located. System 10 allows the component B_{z} of the magnetic field \vec{B} along the axis D of the tapered guide 40 to be measured.

According to one embodiment, hereinafter referred to as the direct operating mode, the control and acquisition device 30 is configured to provide a current pulse in the conductor wire 50. The current pulse has an intensity I and a duration Δt. In the presence of the magnetic field \vec{B} at the tip 42 of the tapered guide 40, a Lorentz force \vec{F} appears in the part of the conductor wire 50 located at the tip 42 of the tapered guide 40, the magnitude F of which is defined by the following relationship:

F=IΔtVB [Math 1]

where V is the speed of the electrons in conductor wire 50.

In direct operating mode, the tapered guide 40 transforms the Lorentz force \vec{F} force into a pulsed ultrasonic bending wave, which remains broadband during its propagation in the tapered guide 40. The magnitude of the ultrasonic bending wave is proportional to the component B_{z} of the magnetic field \vec{B} to be measured, to the intensity I of the current pulse, and to the duration Δt of the current pulse. to be measured, to the intensity I of the current pulse, and to the duration Δt of the current pulse. The bending wave is polarized in the direction of the vector product \vec{I}\hat{ }\vec{B} perpendicular to the plane shown in FIG. 1 defined by axis D and the tangent to conductor wire 50 defining the current vector \vec{I} where conductor wire 50 is rigidly attached to the end of tip 42. Due to its overall tapered shape with a small angle at the apex, the tapered guide 40 promotes the propagation of an acoustic bending mode generated at the tip end 42 to the base 41. The intrinsic impedance of the material making up the tapered guide 40 is equal to the product of the fundamental velocity of a transverse wave in the material and the density of the material. The mechanical radiation impedance of the tip 42 of the tapered guide 40 is defined as the product of the phase velocity of an acoustic wave at the coupling point and the density of the material making up the tapered guide 40. The mechanical radiation impedance is particularly low, typically 3 to 4 times lower than the intrinsic impedance of the material. This characteristic is advantageously suited to efficient transfer of the Lorentz force appearing in the conductor wire 50 rigidly coupled to the tip 42 by bonding. The acoustic wave reaches the electroacoustic transducer 60, which converts it into an electrical signal S, for example a voltage. The control and acquisition device 30 is configured to measure the electrical signal S supplied by the electroacoustic transducer 60 and to deduce from it the magnitude of the component B_{z} of the magnetic field \vec{B} and the polarization of the magnetic field \vec{B} present at the tip 42 of the tapered guide 40.

According to one embodiment, the intensity I of the current pulse is preferably as high as possible, in practice between 1 A and 100 A, preferably about 50 A. According to one embodiment, the duration Δt of the current pulse is as short as possible, for example between 1 ns and 500 ns, preferably about 10 ns. If the magnetic field to be measured corresponds to a magnetic pulse, the duration Δt of the current pulse is shorter than the duration of the magnetic pulse to be measured. In the case where the magnetic field to be measured corresponds to a sinusoidal magnetic field, the duration Δt of the current pulse is less than at least twice the period of the sinusoidal magnetic field to be measured. Generally speaking, if the magnetic field to be measured varies over time, the duration Δt of the current pulse is less than at least twice the period corresponding to the frequency of maximum variation of the magnetic field.

In direct operating mode, the tapered guide 40 advantageously introduces an acoustic propagation delay of 1 μs to 100 μs between the electrical pulse present at the tip 42 of the tapered guide 40 and the supply of the electrical signal by the electroacoustic transducer 60. This avoids interference to the receive amplifier of the control and detection device 30 by direct air coupling between the electrical pulse and the receive electronics.

According to one embodiment, hereinafter referred to as reciprocal operating mode, the control and acquisition device 30 is configured to drive the electroacoustic transducer 60 to generate an acoustic wave in the tapered guide 40. In reciprocal operating mode, the tapered guide 40 is used to propagate the ultrasonic wave from the base 41 to the tip 42. The ultrasonic wave causes the tip 42 to bend. The displacement of tip 42, and therefore of conductor wire 50 in the magnetic field \vec{B} causes an electromotive force FEM to occur in the conductor wire 50. The electromotive force FEM is proportional to the component B_{z} of the magnetic field \vec{B} to be measured. The control and acquisition device 30 is configured to measure the electromotive force FEM at the ends of the conductor wire 50 and to deduce from it the component B_{z} of the magnetic field \vec{B} and the polarization of the magnetic field \vec{B} present at the tip 42 of the tapered guide 40.

According to one embodiment, the conductor wire 50 has a cylindrical cross-section. According to another embodiment, conductor wire 50 has a non-cylindrical cross-section. In this case, the diameter of the conductor wire 50 is equal to the diameter of the disk with the same surface area as the cross-section al area of the conductor wire 50. According to one embodiment, conductor wire 50 has a diameter ranging from 10 μm to 200 μm, for example equal to approximately 40 μm. According to one embodiment, conductor wire 50 comprises a conductive core surrounded by an insulating envelope, for example an enameled wire. According to another embodiment, the conductor wire 50 corresponds to a conductive track deposited on the tapered guide 40.

According to one embodiment, the tip 42 of the tapered guide 40 comprises a surface 44, hereinafter referred to as the support surface 44, on which the portion 52 of the conductor wire 50 rests.

According to one embodiment, the support surface 44 is flat and perpendicular to the axis D of the tapered guide 40. According to another embodiment, the support surface 44 is inscribed in a disk. The diameter of the disc in which the support surface 44 is inscribed is referred to as the diameter of the support surface 44. According to one embodiment, the support surface 44 is not flat. In this case, the diameter of the support surface 44 is the diameter of the disk in which the support surface 44 is inscribed when viewed along the axis D.

According to one embodiment, the support surface 44 has a diameter between the diameter of the conductor wire 50 and five times the diameter of the conductor wire 50, for example between twice and five times the diameter of the conductor wire 50. According to one embodiment, the support surface 44 has a diameter between twice and five times the diameter of the conductor wire 50. According to one embodiment, support surface 44 has a diameter equal to the diameter of conductor wire 50. The periphery of support surface 44 then constitutes a support surface protecting conductor wire 50. The closer the diameter of conductor 50 is to the diameter of support surface 44, the less propagation effects are felt in the vicinity of tip 42. As an example, for a conductor wire 50 with a diameter of 40 μm, the diameter of support surface 44 may be close to 100 μm.

In addition, to avoid crushing the conductor wire 50 during measurements, a notch with a depth equal to the diameter of the conductor wire 50 can be made in the plane of the support surface 44 so as to bury the conductor wire 50 in the tip 42.

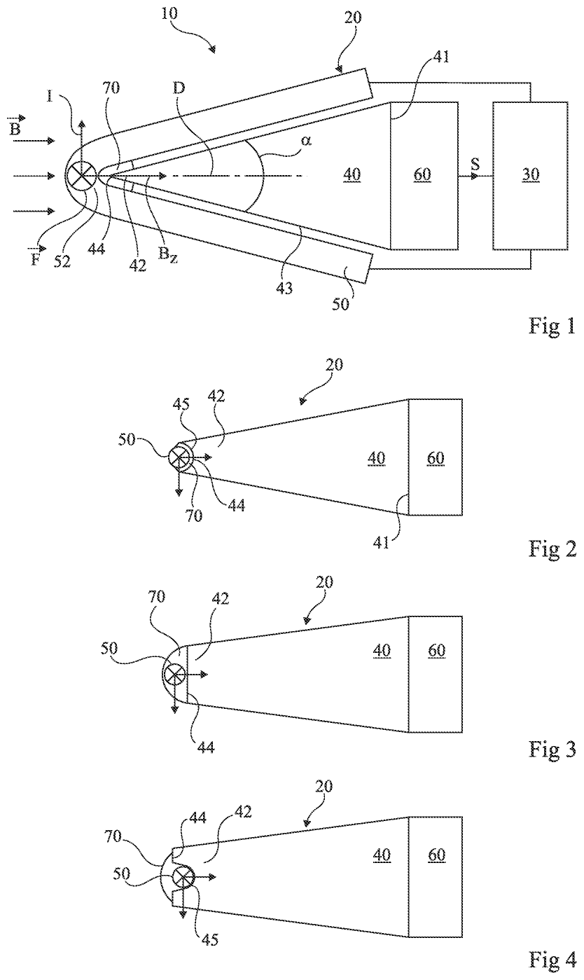

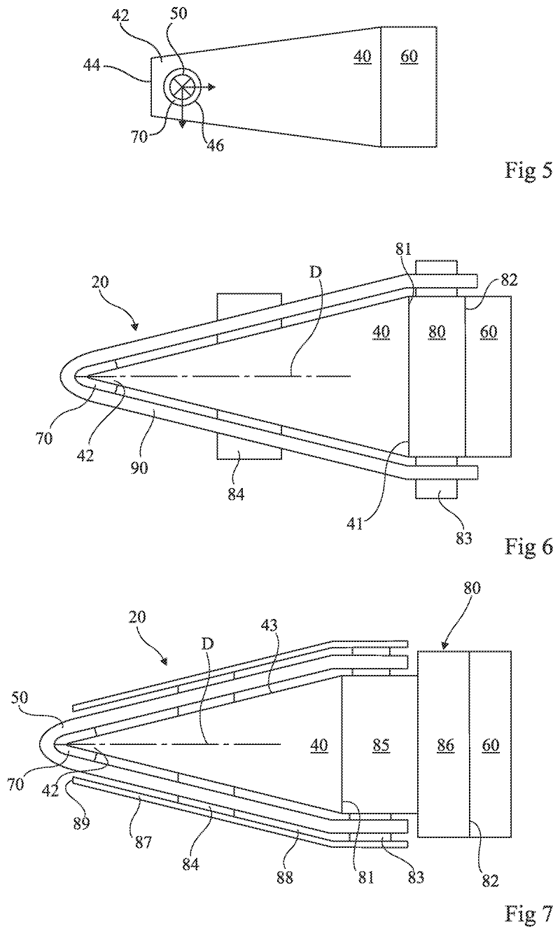

FIG. 2, FIG. 3, FIG. 4, and FIG. 5 are schematic, partial cross-sectional views of other embodiments of probe 20. The sectional plane of FIGS. 2 to 5 contains the axis D of the tapered guide 40 and is perpendicular to the sectional plane of FIG. 1.

In the embodiment shown in FIG. 2, the diameter of the support surface 44 is equal to the diameter of the conductor wire 50, and the support surface 44 comprises a notch 45 in which the conductor wire 50 is embedded. This design is particularly suitable for low-magnitude magnetic fields. The bonding material 70 can be distributed in the notch 45. The portion 52 of the conductor wire 50 resting on the support face 44 extends substantially straight along an axis perpendicular to the axis D of the tapered guide 40. Preferably, the length of the straight portion 52 of the conductor wire 50 does not exceed half a wavelength of the phase velocity of the transverse waves, i.e. typically less than 0.5 mm at 1 MHz and 0.1 mm at 5 MHz. The embodiment illustrated in FIG. 2 enables magnetic field \vec{B} detection with the best spatial resolution compared with the methods illustrated in FIGS. 3 to 5.

In the embodiment shown in FIG. 3, the support surface 44 is flat and the diameter of the support surface 44 is approximately 3 times the diameter of the conductor wire 50. Conductor wire 50 lies flat on support surface 44 and is protected by bonding material 70.

In the embodiment shown in FIG. 4, the diameter of the support surface 44 is approximately 3 times the diameter of the conductor wire 50, and the support surface 44 comprises a notch 45 in which the conductor wire 50 is embedded.

In the embodiment shown in FIG. 5, the tapered guide 40 comprises a through opening 46 in the tip 42 close to the tip end 42, for example at a distance from the tip end 42 varying from once to twice the diameter of the conductor wire 50. The diameter of through-opening 46 is slightly larger than the diameter of conductor wire 50, and conductor wire 50 passes through opening 46. Conductor wire 50 is rigidly coupled to tapered guide 40 by bonding material 70 or by compressing and deforming the end of tip 42, which slightly pinches conductor wire 50.

The embodiments shown in FIGS. 3, 4, and 5 are advantageously more robust than the embodiment shown in FIG. 2. In particular, the embodiments shown in FIGS. 3, 4, and 5 are suitable for applications where it is envisaged that the probe 20 can be brought into contact with a magnetized surface. In addition, the risk of crushing the conductor wire 50 in the embodiments illustrated in FIGS. 4 and 5 is reduced compared with the embodiments illustrated in FIGS. 2 and 3.

The larger the diameter of the support surface 44, the less disturbance to the measurement when the tip 42 comes into contact with a hard surface. This is because the radiation impedance of tip 42 drops considerably as the end of tip 42 is approached. Its blockage by a hard surface could limit the magnitude of the mechanical impulse generated by the Lorentz force applied to a small, laterally free volume of material. This could distort the measurement by reducing the magnitude of the signal. In addition, contact of the tip 42 with a solid medium can generate ultrasonic waves in the medium, which can return to the tip 42 and distort the measurement.

Advantageously, the lateral dimensions of the tip 42 of probe 20 are at least ten times smaller than the lateral dimensions of Hall effect probes currently available on the market.

According to one embodiment, conductor wire 50 comprises at least one core of an electrically conductive material, optionally surrounded by an electrically insulating envelope. According to one embodiment, the conductive material is chosen from copper, a material the electron mobility of which is greater than 30 cm²/V/s (notably gold, silver, or a semiconductor material such as graphene), or a mixture of at least two of these compounds. The nature of the conductor making up the conductor wire 50 is important, whether for direct operation or reciprocal operation when one wishes to increase the sensitivity of the probe 20 to low-intensity magnetic fields. By default, an enameled copper wire 50 can be used for magnetic fields ranging from a few milliteslas to several tens of Tesla. But for applications requiring high sensitivity to low-intensity magnetic fields, typically when these are comparable to or less than the millitesla or the earth's magnetic field, materials with higher electron mobility than copper (which is equal to 30 cm²/V/s) can be used, such as gold (43 cm²/V/s), silver (68 cm²/V/s) or semiconductor materials like graphene. Alternatively, a graphene-coated copper wire with electron mobility of up to 200,000 cm²/V/s can be used. The electrical voltage appearing at the terminals of the conductor wire 50 in reciprocal mode is thus increased by the higher electron mobility of the material making up the conductor wire 50, and the 20 probe produces a usable signal and an improved signal-to-noise ratio at weaker magnetic fields, compared with the case of simply using an enameled copper conductor wire 50.

According to one embodiment, the tapered guide 40 is made of a solid, non-magnetic material, in particular a material selected from the group comprising glass, silicon, ceramics, non-magnetic metals (in particular aluminum, copper or titanium), austenitic steel and non-magnetic metal alloys, in particular aluminum-, copper- and/or titanium-based alloys.

Thanks to its tapered geometric shape, the tapered guide 40 provides an advantageous thermal buffer between the measurement zone at the tip 42 and a reception zone at the electroacoustic transducer 60. The measurement zone can then be brought to a high temperature of several hundred degrees Celsius, while the receiving zone can be subjected to a lower temperature compatible with the temperature range tolerated by the electroacoustic transducer 60.

Bonding material 70 can be a cyanoacrylate resin, or an epoxy resin, or a polyimide resin, or a ceramic resin, or a molten glass, or an enamel coating the conductor wire 50. According to one embodiment, the bonding material 70 is adapted to withstand high temperatures, for example up to 1000° C., or up to the lower of the melting temperature of the tip 42 of the tapered guide 40, and the melting temperature of the conductor wire 50. Bonding material 70 corresponds, for example, to the high-temperature adhesive marketed under the name Ceramabond by the Aremco company.

In the direct operating mode, acoustic transducer 60 is configured to receive an acoustic wave and provide an analog electrical signal, such as a voltage or current, hereinafter referred to as the measurement signal. The magnitude of the measurement signal depends on the magnitude of the acoustic wave, and is preferably proportional to the magnitude of the acoustic wave. In the direct operating mode, the acoustic transducer 60 receives a packet and provides an electrical measurement signal comprising at least one peak, and generally several positive and negative peaks. In the reciprocal operating mode, acoustic transducer 60 is configured to receive an analog electrical signal, such as a voltage or current, hereinafter referred to as a control signal, and output an acoustic wave. The magnitude of the acoustic wave depends on the magnitude of the control signal, and is preferably proportional to the magnitude of the control signal. Acoustic transducer 60 can be a transverse wave acoustic transducer. According to one embodiment, acoustic transducer 60 is a piezoelectric transducer or an electromagnetic acoustic transducer. Transducer 60 corresponds, for example, to the piezoelectric transducer marketed by Olympus under the name V153, which can have a center frequency of around 1 MHz.

FIG. 6 is a schematic, partial cross-sectional view of a further embodiment of the probe 20. The probe 20 shown in FIG. 6 comprises all the elements of the probe 20 shown in FIG. 1 and additionally includes a straight acoustic waveguide 80 interposed between the tapered guide 40 and the electroacoustic transducer 60. The straight acoustic waveguide 80 has a constant cross-section and extends rectilinearly, and is hereinafter referred to as straight guide 80. According to one embodiment, the straight guide 80 extends along the axis D and comprises two opposing faces 81 and 82. The electroacoustic transducer 60 is attached to face 82 of straight guide 80. According to one embodiment, the tapered guide 40 and the straight guide 80 are separate parts. The base 41 of the tapered guide 40 is then attached to the face 81 of the straight guide 80. In another embodiment, the tapered guide 40 and the straight guide 80 are manufactured from a single piece. The base 41 of the tapered guide 40 is then included in the face 81 of the straight guide 80. In the embodiment illustrated in FIG. 6, the straight guide 80 has a cylindrical shape with a circular base, and the face 81 of the straight guide 80 has the same diameter as the base 41 of the tapered guide 40.

The probe 20 also includes a support 83 for the tapered guide 40, attached to the straight guide 80. Support 83 is made of an electrically insulating material, such as plastic, especially a polymer. In particular, the support 83 enables the tapered guide 40 to be handled. The conductor wire 50 can be attached to the support 83. The probe 20 may also comprise an additional support 84 attached to the tapered guide 40, for example halfway up the tapered guide 40 between the tip 42 and the base 41. The conductor wire 50 can be attached to the additional support 84. The additional support 84 is made of an electrically insulating material, for example plastic, in particular a polymer.

FIG. 7 is a schematic, partial cross-sectional view of a further embodiment of probe 20. The probe 20 shown in FIG. 7 comprises all the elements of the probe 20 shown in FIG. 6, with the difference that the straight guide 80 comprises two successive circular-based cylindrical portions 85 and 86 of different diameters. The face 81 of the straight guide 80 has the same diameter as the base 41 of the tapered guide 40, and the face 82 of the straight guide 80 has substantially the same diameter as the electroacoustic transducer 60. In the embodiment shown in FIG. 7, the probe 20 further comprises a shell 87 completely surrounding the side wall 43 of the tapered guide 40. In the case where the tapered guide 40 has a conical shape, the shell 87 may correspond to a hollow truncated cone. A gap 88 is provided between the shell 87 and the tapered guide 40 so that the shell 87 is not in direct contact with the tapered guide 40. The shell 87 can be held by the support 83. Shell 87 can be made of a metallic material. The shell 87 comprises an opening 89 through which emerges the tip 42 of the tapered guide 40 and the portion 52 of the conductor wire 50 folded over the tip 42. The shell 87 protects the tapered guide 40 and forms a shield for the parts of the conductor 50 extending along the side wall 43 of the tapered guide 40.

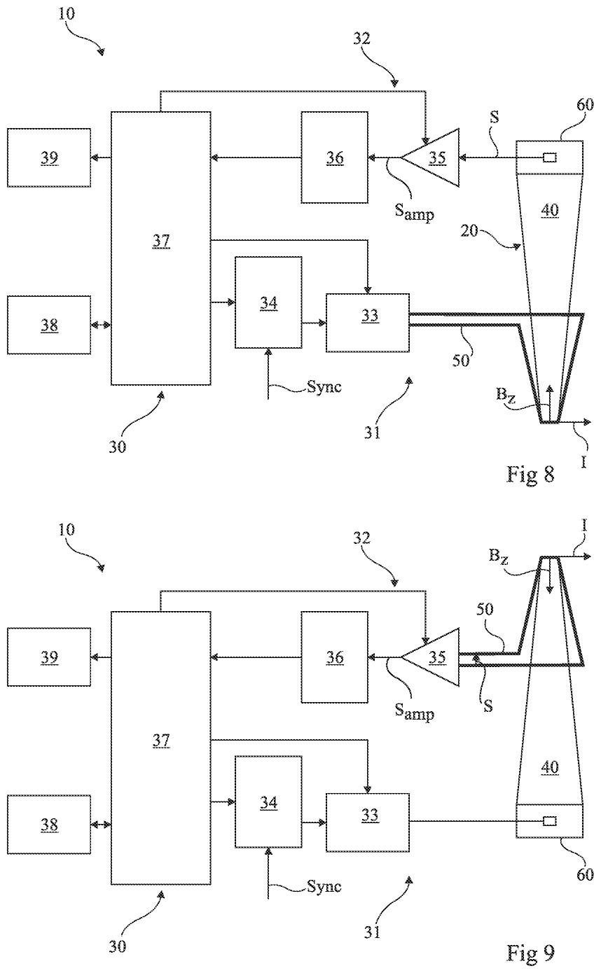

FIG. 8 illustrates a block diagram of the sensing system 10, representing one embodiment of the control and acquisition device 30 for implementing the direct operating mode. According to one embodiment, electroacoustic transducer 60 is a piezoelectric transducer.

The control and acquisition device 30 includes a control chain 31 and an acquisition chain 32. The control chain 31 comprises:
a generator 33 of current pulses in the conductor wire 50 connected to the two ends of the conductor wire 50; and
a control module 34 for the current pulse generator 33, which receives a Sync synchronization signal.

The acquisition chain 32 comprises:
a programmable amplifier 35 receiving the analog measurement signal S supplied by the electroacoustic transducer 60 and providing an amplified analog measurement signal Sₐₘₚ substantially equal to the measurement signal S multiplied by an amplification gain G; and
a processing module 36 receiving the amplified measurement signal supplied by amplifier 35.

The control and acquisition device 30 further comprises:
a microcontroller 37 connected to amplifier 35, processing module 36, control module 34, and generator 33;
a computer 38 connected to microcontroller 37; and
a human-machine interface 39 connected to microcontroller 37 and/or computer 38, including a display screen.

Alternatively, the control module 34 and/or the processing module 36 can be integrated into the microcontroller 37.

The control and acquisition device 30 illustrated in FIG. 8 is configured to generate a current pulse in the conductor wire 50 having an intensity I and a duration Δt, possibly occurring after the elapse of a delay T following a pulse of the synchronization signal Sync in the case of synchronous measurement.

Computer 38 is configured to exchange signals with microcontroller 37, for example via a UART (Universal asynchronous receiver-transmitter) port, including values for delay T, duration Δt, current I, and the gain value G of programmable amplifier 35.

According to one embodiment, the value of the gain G of the programmable amplifier 35 is determined from the magnitude B_{z} of the magnetic field determined during the previous measurement. The lower the magnitude B_{z} determined during the previous measurement, the higher the gain value G, for example in steps corresponding to magnitude B_{z} measurement ranges.

According to one embodiment, the measurement process is triggered by the Sync synchronization signal if the measurement is synchronous. According to another embodiment, the measurement process is triggered automatically and periodically with a user-defined measurement period if the measurement is asynchronous. In this case, the measurement period is preferably longer than the damping time of the acoustic pulse propagating in the tapered guide 40 due to the preceding current pulse.

According to one embodiment, the generator 33 applies a current pulse of intensity I in the conductor wire 50 coupled to the tip 42 of the tapered guide 40 with a delay T and a duration Δt defined in the control module 34. In the presence of the magnetic field \vec{B} an ultrasonic acoustic wave, the peak magnitude of which is proportional to the component B_{z}, rises from the tip 42 towards the base 41 of the tapered guide 40. The acoustic wave is converted into an electrical measurement signal S by the acoustic transducer 60 coupled to the base 41, and the electrical measurement signal S is amplified by the programmable amplifier 35 to provide the amplified measurement signal Sₐₘₚ.

According to one embodiment, the processing module 36 is configured to detect the peak magnitude of the amplified measurement signal Sₐₘₚ, and supply an analog value of the detected peak magnitude to the microcontroller 37. According to one embodiment, the processing module 36 is further configured to determine a binary value Polar I/O representative of the positive or negative sign of the first pulse of the amplified measurement signal Sₐₘₚ. Indeed, the phase of the acoustic wave changes by 180° depending on whether the polarization of the component B_{z} is oriented in one or the opposite direction. The microcontroller 37 may also include an analog/digital converter adapted to receive the analog value of the detected peak magnitude and provide a digital signal of the peak magnitude.

According to one embodiment, microcontroller 37 is configured to receive the amplified measurement signal Sₐₘₚ directly and to sample the amplified measurement signal Sₐₘₚ, for example with a depth of 10 to 16 bits and at a rate of 5 to 12 mega samples per second over a time window of 1 μs to 100 μs. According to one embodiment, the microcontroller 37 is configured to interpolate the measurement points so as to finely reconstitute the amplified measurement signal and obtain a precise value for the peak magnitude and phase of the amplified measurement signal.

According to another embodiment, the microcontroller 37 is configured to determine the Fourier transform of the amplified measurement signal Sₐₘₚ. Preferably, the Fourier transform is determined from the time trace of the amplified measurement signal Sₐₘₚ including the peaks of the amplified measurement signal Sₐₘₚ, and excluding the parasitic coupling of the current or voltage pulse so that only the peaks due to the reception of the acoustic wave packet by the transducer 60 with a zero measurement signal before its arrival and after its arrival remain in the time trace.

According to one embodiment, the amplified measurement signal Sₐₘₚ is processed so that its values are zero after the fourth or fifth zero crossing of the amplified measurement signal Sₐₘₚ, which corresponds to the moment when the bulk of the acoustic wave packet has been received by the transducer 60 and the tail of the acoustic wave packet is entered. The spectral line of maximum magnitude in the spectrum obtained corresponds to the center frequency of the acoustic wave packet. The magnitude of the spectral line is representative of the maximum magnitude value of the amplified measurement signal Sₐₘₚ.

Determining the peak magnitude of the amplified measurement signal Sₐₘₚ from the Fourier transform of the amplified measurement signal Sₐₘₚ rather than directly from the amplified measurement signal Sₐₘₚ is more accurate and more independent of the analog noise present in the amplified measurement signal Sₐₘₚ. This enables access to weak magnetic fields close to the earth's magnetic field. In these extreme cases, sensitivity is increased by replacing the current pulse with a pulse train, comprising for example 2 to 10 and preferably 4 equidistant current pulses, with a carrier centered on the center frequency of the electromechanical transducer 60. Furthermore, the Fourier transform of the amplified measurement signal Sₐₘₚ is independent of the propagation time of the acoustic waves in the tapered waveguide 40. The effect of a change in temperature of the tapered waveguide 40 is therefore reduced to an advance or delay in the arrival of the acoustic wave packet at the transducer 60, i.e. simply a phase change in Fourier space.

Microcontroller 37 is configured to determine the field value B_{z} by multiplying the peak value by a calibration coefficient. The value of the magnetic field B_{z} and its polarization (north, south) are displayed on display 39 in a chosen unit of measurement or transmitted to computer 38 for further processing.

According to one embodiment, the control and acquisition device 30 can drive one, two or more probes 20 from the same synchronization signal Sync, each of the probes 20 being able to be excited with the same or a different delay T relative to the other probes 20, so that the spatial and temporal sampling can be multiplied by the number of probes 20 used. If several probes 20 are excited with slightly different T delays and arranged at virtually the same location of a relatively spatially extensive but very rapidly oscillating magnetic source, the number of magnetic field sampling points can be multiplied by the number of probes 20 used.

FIG. 9 shows a block diagram of the detection system 10, illustrating an embodiment of the control and acquisition device 30 for implementing the reciprocal operating mode. The control and acquisition device 30 shown in FIG. 9 comprises the same elements as the control and acquisition device 30 shown in FIG. 8, with the difference that the measurement signal Sₐₘₚ received by the amplifier 35 corresponds to the voltage at the terminals of the conductor wire 50, and that the current pulse generator 33 is replaced by a voltage pulse generator 33 supplied to the transducer 60.

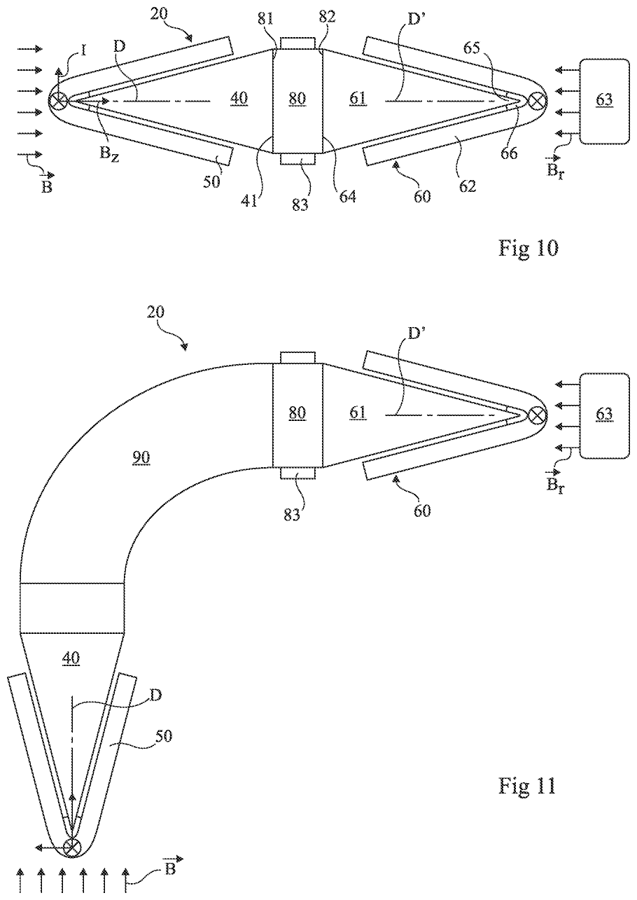

FIG. 10 is a schematic, partial cross-sectional view of the electroacoustic transducer 60 of probe 20. In FIG. 10, electroacoustic transducer 60 is a transverse-wave electroacoustic transducer comprising an acoustic waveguide 61, an electrically conductive wire 62 and a permanent magnet 63.

Acoustic waveguide 61 may have the same shape as tapered guide 40, i.e. a tapered shape along an axis D′ from a base 64 to an end 65, hereinafter referred to as the tip, opposite base 64. The acoustic waveguide 61 is hereinafter referred to as the tapered guide 61. According to one embodiment, the tapered guide 61 has the general shape of a cone of revolution of axis D′, possibly truncated, with a small angle at the apex. According to one embodiment, the conductor wire 62 is bent over the tip 65 of the tapered guide 61 and secured to the tip 65 by a bonding material 66. Conductor wire 62 forms a half-loop that is substantially coplanar with the half-loop formed by conductor wire 50. The permanent magnet 63 is located close to the tip 65 of the tapered guide 61, preferably almost in contact with the tapered guide 61 but not touching it, for example at a distance of 100 μm for a magnet with a diameter of 2 mm or 3 mm. Permanent magnet 63 generates a reference magnetic field \vec{Bᵣ} at the tip 65 of the tapered guide 61. In FIG. 10, the axis of revolution D of the tapered guide 40 and the axis of revolution D′ of the tapered guide 61 are parallel, preferably coincident.

In FIG. 10, the probe 20 further comprises the straight guide 80 comprising two opposing faces 81 and 82 and a support element 83 for the straight guide 80. In the embodiment shown in FIG. 10, the straight guide 80 has a cylindrical shape with a circular base. According to one embodiment, the tapered guide 61, the straight guide 80, and the tapered guide 40 are separate parts. The base 41 of the tapered guide 40 is attached to the face 81 of the straight guide 80, and the base 64 of the tapered guide 61 is attached to the opposite face 82 of the straight guide 80. According to another embodiment, the tapered guide 61, the straight guide 80, and the tapered guide 40 are manufactured from a single piece. The base 41 of the tapered guide 40 is then included in the face 81 of the straight guide 80, and the base 64 of the tapered guide 61 is then included in the face 82 of the straight guide 80.

The electroacoustic transducer 60 shown in FIG. 10 operates as follows: when the ultrasonic wave coming from the tapered guide 40, whether in the direct or reciprocal mode of operation, arrives at the base 64 of the tapered guide 61, it propagates to the tip 65 of the tapered guide 61, amplifying as it approaches the tip 65. The bending mode forced on the tip 65 of the tapered guide 61 generates, in the presence of the reference magnetic field \vec{Bᵣ}, an electromotive force FEM in the conductor wire 62. The result is a low-cost method for detecting a quasi-point broadband ultrasonic wave, based on the same principle as the method for generating the broadband ultrasonic wave used to measure the field B_{z}.

FIG. 11 is a schematic, partial cross-sectional view of a variant of the probe 20 shown in FIG. 10. The probe 20 shown in FIG. 11 comprises all the elements of the probe 20 shown in FIG. 10 and additionally includes a curved acoustic waveguide 90 interposed between the tapered guide 40 and the straight guide 80. The curved acoustic waveguide 90 has a constant cross-section and extends along a curve. Curved acoustic waveguide 90 is hereinafter referred to as curved guide 90. Alternatively, the curved waveguide 90 is interposed between the straight waveguide 80 and the tapered waveguide 61. The tapered waveguide 40, the curved waveguide 90, the straight waveguide 80, and the tapered waveguide 61 may be separate parts, or they may be manufactured as a single piece. The curved guide 90 may have a circular cross-section.

The curved guide 90 allows the axis of revolution D of the tapered guide 40 and the axis of revolution D′ of the tapered guide 61 to be non-parallel, which can facilitate mounting the probe 20 on a positioning arm. The curvature condition of the curved guide 90 is that the radius of curvature is large compared to the diameter of the curved guide 90, typically at least 3 times larger, so that the propagation of ultrasound waves in the curved guide 90 is only slightly disturbed.

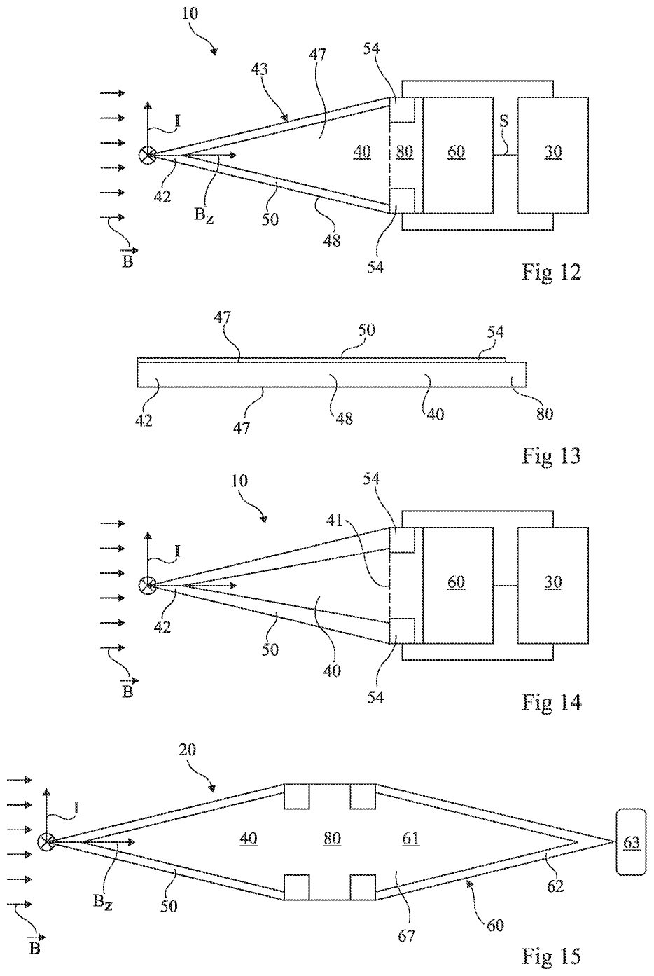

FIG. 12 is a schematic, partial top view of another embodiment of the system for detecting a magnetic field 10, and FIG. 13 is a side view of the probe 20 of the system for detecting a magnetic field 10 of FIG. 12.

The system for detecting a magnetic field 10 shown in FIG. 12 comprises all the elements of the system for detecting a magnetic field 10 shown in FIG. 6, in which the tapered guide 40 has the shape of a right triangular prism, and the straight guide 80 has the shape of a right-angled parallelepiped. The side wall 43 of the tapered guide 40 comprises two main faces 47, each corresponding, for example, to an isosceles triangle, and flanks 48 corresponding to rectangles. The tapered guide 40 can be made of any of the materials described above for the embodiment illustrated in FIG. 1. In particular, if the tapered guide 40 is made of a conductive material, an insulating layer, not shown, can be interposed between the tapered guide 40 and the conductive track 50. The tapered guide 40 can be produced on a wafer made of glass or a semiconductor material, such as silicon, with a thickness of around 100 μm and preferably less than 1000 μm using photo-etching techniques. In the present embodiment, the conductor wire 50 corresponds to a conductive track deposited on a triangular main face 47 of the tapered guide 40, for example by sputtering or electrochemical growth. Electrical connections are made by means of connecting wires attached to conductive pads 54 located, for example, on the straight guide 80. Conductive track 50 can be micrometer-wide at the tip 42 of the tapered guide 40. As shown in FIG. 12, conductive track 50 has a substantially constant width.

When the tapered waveguide 40 corresponds to a prism, the bending mode in the tapered waveguide 40 that appears in operation corresponds more precisely to Lamb's first antisymmetric mode A₀.

FIG. 14 is a schematic, partial top view of a variant of the probe 20 in which the conductive track 50 increases in width from the tip 42 to the base 41 of the tapered guide 40, thereby reducing the ohmic resistance of the conductive track 50.

According to one embodiment, the triangular face 47 of the tapered guide 40 is partially covered with an electrically conductive layer providing electrical shielding.

FIG. 15 is a schematic, partial top view of a variant of the probe 20 and electroacoustic transducer 60 of the system for detecting a magnetic field 10 shown in FIG. 12. The probe 20 and electroacoustic transducer 60 shown in FIG. 15 comprise all the elements of the probe 20 and electroacoustic transducer 60 shown in FIG. 10, with the difference that the tapered guide 40, the straight guide 80, and the tapered guide 61 of the electroacoustic transducer 60 each have the shape of a prism. More specifically, the tapered guide 40 has the structure described above in relation to FIGS. 12 and 13. The electroacoustic transducer 60 is a transverse-wave electroacoustic transducer comprising a prismatic guide 61 having the same shape as the tapered guide 40. In addition, the conductor wire 62 corresponds to a conductive track deposited on a triangular face 67 of the tapered guide 61, for example by sputtering or electrochemical growth. The tapered guide 40, the straight guide 80, and the tapered guide 61 can be manufactured from a single piece by cutting a wafer.

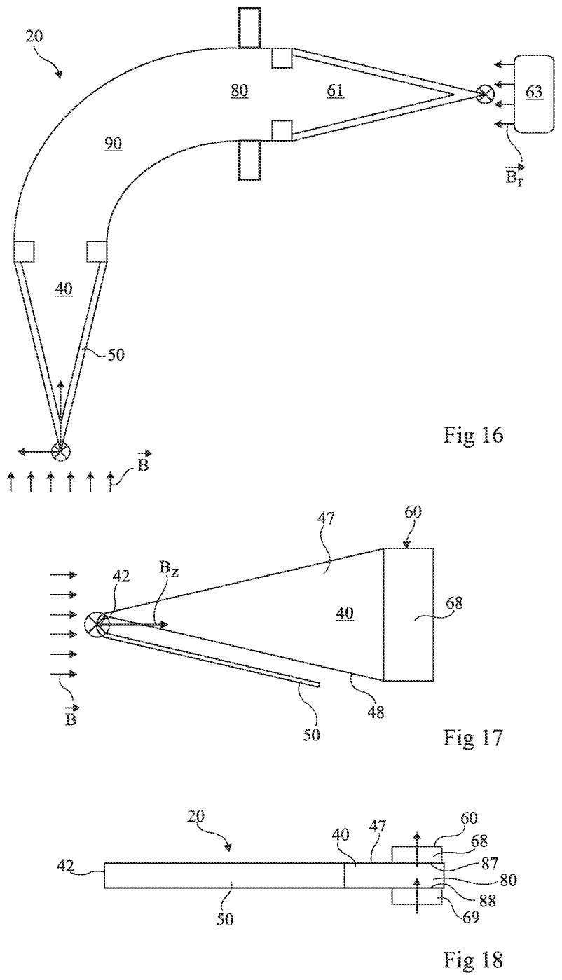

FIG. 16 is a schematic, partial cross-sectional view of a variant of the probe 20 and electroacoustic transducer 60 of the system for detecting a magnetic field 10 shown in FIG. 15. The probe 20 and electroacoustic transducer 60 shown in FIG. 16 comprise all the elements of the probe 20 and electroacoustic transducer 60 shown in FIG. 11, with the difference that the tapered guide 40, curved guide 90, straight guide 80, and tapered guide 61 of the electroacoustic transducer 60 have prismatic structures. The tapered guide 40, the curved guide 90, the straight guide 80, and the tapered guide 61 can be manufactured from a single piece by cutting a wafer.

FIG. 17 is a schematic, partial top view of another embodiment of the probe 20, and FIG. 18 is a side view of the probe 20 of FIG. 17.

The probe 20 comprises all the elements of the probe 20 shown in FIG. 12, with the difference that the tapered guide 40 is made of an electrically conductive material, for example metal, and that the conductor wire 50 corresponds to an electrically conductive blade extending along a flank 48 of the tapered guide 40 from the tip 42 of the tapered guide 40, at a distance from the flank 48 of the tapered guide 40, and which is connected to the tapered guide 40 at the tip 42 of the tapered guide 40. According to one embodiment, the tapered guide 40 and the conductor wire 50 are manufactured from a single piece by cutting a metal plate. In particular, the radius and shape of the conductor wire 50 at the tip 42 of the tapered guide 40 can be adapted to optimize the Lorentz force on a segment of material oriented perpendicular to the axial component B_{z}. According to one embodiment, conductor 50 is arranged in a “U” shape at the tip 42 of the tapered guide 40.

According to one embodiment, the electroacoustic transducer 60 comprises first and second piezoelectric plates 68, 69 fixed to the center of the straight guide 80 of the probe 20, for example by bonding or brazing, the first piezoelectric plate 68 being fixed to a face 87 of the straight guide 80, coplanar with the triangular face 47 of the tapered guide 40, and the second piezoelectric plate 69 being fixed to the face 88 of the straight guide 80 opposite the face 87.

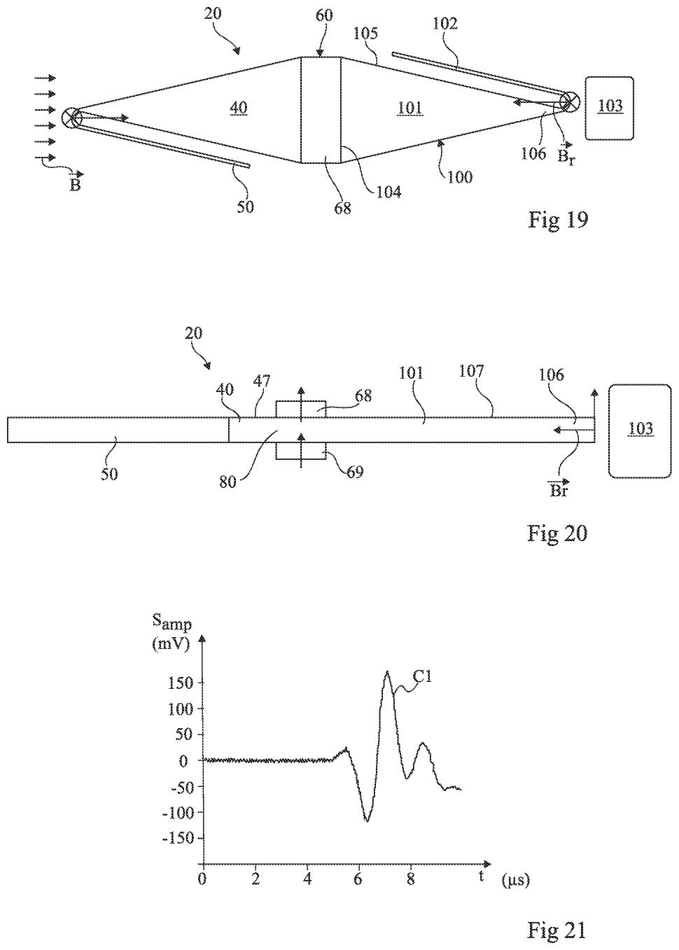

FIG. 19 is a schematic, partial top view of another embodiment of the probe 20, and FIG. 20 is a side view of the probe 20 of FIG. 19.

The probe 20 shown in FIG. 19 comprises all the elements of the probe 20 shown in FIG. 17, and also includes a calibration device 100 comprising an acoustic waveguide 101, a conductor wire 102, and a permanent magnet 103 emitting a reference magnetic field \vec{Bᵣ}. The acoustic waveguide 101 comprises a base 104 which is connected to the tapered guide 40 via the straight guide 80. Acoustic waveguide 101 may have the same structure as tapered guide 40 and is hereinafter referred to as tapered guide 101. Conductor wire 102 may have the same structure as conductor wire 50. This means that the tapered guide 101 is made of an electrically conductive material, e.g. metal, and that the conductor wire 102 corresponds to an electrically conductive blade extending along a flank 105 of the tapered guide 101 from the tip 106 of the tapered guide 101, away from the flank 105 of the tapered guide 101, and which is connected to the tapered guide 101 at the tip 106 of the tapered guide 101.

The tapered guide 40, the guide wire 50, the straight guide 80, the tapered guide 101, and the conductor wire 102 are made of an electrically conductive material, such as metal. According to one embodiment, the tapered guide 40, the conductor 50, the straight guide 80, the tapered guide 101, and the conductor wire 102 are made in one piece by cutting or etching a metal plate.

According to one embodiment, the probe 20 shown in FIGS. 19 and 20 is a self-calibrating biconical probe. According to one embodiment, probe 20 operates in the reciprocal mode described above. Ultrasonic signals are supplied simultaneously by the piezoelectric plates 68 and 69. According to one embodiment, piezoelectric plates 68 and 69 are P-polarized ferroelectric plates with axes perpendicular to face 47. They are mounted opposite each other and vibrate in phase opposition when subjected to an electrical pulse, for example between 50 V and 500 V, and preferably around 100 V. This generates an antisymmetrical Lamb mode AO starting from the center of the probe 20 both towards the tip 42 of the tapered guide 40 and towards the tip 104 of the tapered guide 101.

The tapered guide 101 associated with the known reference field \vec{Bᵣ} automatically determines the field to be measured B_{z} which is proportional to it, with a proportionality component directly dependent on the ratio between the peak magnitude A_{cm} of the ultrasonic measurement signal and the peak magnitude A_{cr} of the ultrasonic reference signal. The tip 42 of the tapered guide 40 vibrates with a peak magnitude perpendicular to the face 47 of the tapered guide 40. In the presence of the magnetic field B_{z}, this generates the measurement electromotive force FEMₘ. The tip 106 of the tapered guide 101 vibrates with a peak magnitude perpendicular to the main face 107 of the tapered guide 101. In the presence of the field Br, this generates the reference electromotive force FEMᵣ.

The magnetic field B_{z} to be measured is obtained by the following relationship:

[Math 2]

$${B}_{z} = K \frac{{A}_{cm}}{{A}_{cr}} {B}_{r}$$

where K is a correction factor.

The ratio of the peak magnitudes A_{cm} and A_{cr} can be determined directly from the determination of each peak magnitude A_{cm} and A_{cr}. Alternatively, the Fourier transforms of the sampled measurement and reference signals can be determined and the ratio of the peak magnitudes A_{cm} and A_{cr} can be obtained by determining the ratio of the magnitudes of the spectral components of the spectra of the measurement and reference signals at a frequency corresponding to the case where the width of the piezoelectric plates 68 and 69 is equal to half the wavelength of the Lamb mode A0.

The strength of the reference magnetic field \vec{Bᵣ} emitted by the permanent magnet 63 can vary from 10 mT to 500 mT. According to one embodiment, each tapered guide 40 and 101 and the straight guide 80 has a thickness of 0.05 mm to 0.5 mm, preferably 0.05 mm to 0.3 mm, for example about 0.2 mm. According to one embodiment, each tapered guide 40 and 101 has an apex angle of less than 5°, and the base of the triangular face 47, 67 has a width of less than 1 mm. By way of example, the biconical probe 20 may have a thickness equal to 0.1 mm, a total length, measured from the tip 42 of the tapered guide 40 to the tip 104 of the tapered guide 101, equal to 20 mm, a width equal to 1 mm, each tapered triangular guide 40 and 101 having a height of approximately 9.5 mm, and each conductor wire 50 and 102 having a width equal to 100 μm, and a thickness equal to 100 μm.

According to one embodiment, the working frequency lies between 500 kHz and 10 MHz, and preferably at a frequency corresponding to the case where the product of the frequency and the thickness of each tapered guide 40 and 101 is close to 1 MHz·mm. By way of example, for tapered guides 40 and 101 each having a thickness equal to 0.1 mm, the working frequency may be close to 10 MHz.

According to one embodiment, it can be determined that the tapered guide 40 is undamaged by monitoring the peak echo from the tapered guide 40 to the tapered guide 101. If the tapered guide 40 is damaged, the signal will be modified. Simply check the magnitude of the echo coming from the tapered guide 40 with a delay equal to the total transit time from one end of the probe 20 to the other.

According to another embodiment, each tapered guide 40 and 101 and the straight guide 80 can be made of an insulating material, for example by etching into an insulating plate. In this case, the conductor wires 50 and 102 can be produced by depositing a conductive ink or paste on the flanks of the tapered guide 40 and 101.

According to one embodiment, two probes 20 can be arranged in a biaxial arrangement at 90° to each other, or three probes 20 can be arranged in a triaxial arrangement at 90° to each other, with the probes joined at the tips. This enables local determination of the 2D or 3D vector components of the magnetic field to be measured.

According to one embodiment, tapered guide 40 and tapered guide 101 have the same dimensions, so that the measurement signals relating to the wave packets received from conductor wire 50 and conductor wire 102 are identical when the reference magnetic field Br is equal to the component B_{z} to be measured. In the event of a deviation greater than a certain tolerance, e.g. 3%, a correction factor K can be adjusted, close to unity and reflecting a difference in performance between the tapered guide 40 and the tapered guide 101.

According to one embodiment, the system for detecting a magnetic field 10 is used as a magnetized surface reading head. The permanent magnet 63 supplying the reference magnetic field Br can be made very small and encapsulated in an enclosure for confining the field lines Br. The value of Br may be lower or higher than the maximum conceivable magnitude of the field to be measured B_{z}. However, it is sufficiently large for the signal-to-noise ratio to allow a measurement of the reference field Br that is reproducible to better than 1% from one measurement to the next, or another predefined tolerance of between 0.1% and 5% for system 10.

Examples of applications of the above-described embodiments of the magnetic field measurement system include the study of the electromagnetic compatibility of components, the characterization of inductive components or high-intensity inductive probes, in particular the spreading of remote field lines or electromagnetic leakage through slots or openings in shielding, or the characterization of the magnetic susceptibility of materials. Another application example is the realization of a read head for mapping magnetic fields or reading data stored in magnetic form by detecting a local binary polarization or a field of given magnitude.

The embodiments of the magnetic field measurement system described above enable a transient or oscillating magnetic field to be sampled synchronously, with a high degree of spatial localization and also a high degree of temporal localization via a very short sampling period. In particular, the spatial measurement resolution can be less than 0.1 mm, and the sampling time can be less than 10 ns. In particular, it is possible to measure pulsed magnetic fields with a minimum duration of around 10 ns, or variable magnetic fields with a maximum frequency of the order of 100 MHz.

Tests were carried out. For the first, second, third, fourth, and fifth tests, probe 20 was used to measure the static magnetic field emitted by a permanent magnet composed of an alloy of neodymium, iron, and boron. The permanent magnet is a cylindrical magnet with a circular base and a diameter of 3 mm, placed almost in contact with the tip 42 of the tapered guide 40, the axis of the permanent magnet being aligned with the axis D of the tapered guide 40. For all tests, the electroacoustic transducer 60 is the piezoelectric transducer marketed by Olympus under the name V153, centered on 1 MHz. For all tests, the tapered guide 40 is made of aluminum, and the conductor wire 50 is an enameled copper wire bonded with cyanoacrylate resin to the support surface 44 of the tapered guide 40. For all tests, the amplification gain of the programmable amplifier is equal to 48 dB.

For the first and second tests, probe 20 is used in direct operating mode and the current pulse flowing through wire 50 has a duration Δt equal to 270 ns and a current I equal to 50 A.

In the first test, the probe 20 shown in FIG. 3 is used. The height of the tapered guide 40, measured along its axis of revolution D, is 82 mm and the diameter at the base 41 is 7 mm. The diameter of the support surface 44 is 0.6 mm. The angle at the apex of the tapered guide 40 is 4.6°. Conductor wire 50 has a diameter of 150 μm. The diameter of support surface 44 is therefore four times the diameter of conductor wire 50. The magnetic field of the permanent magnet has a magnitude of 445 mT.

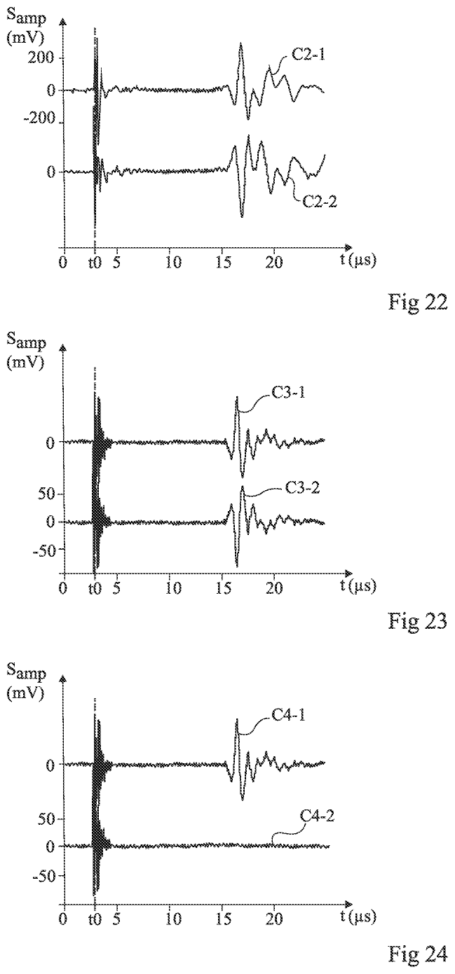

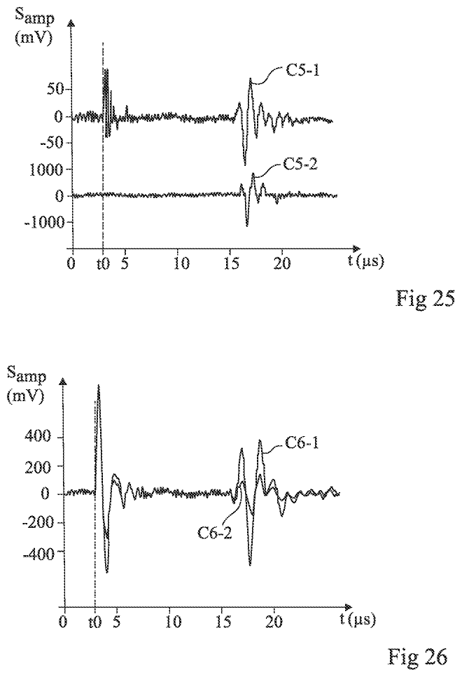

FIG. 21 illustrates an evolution curve C1 as a function of time of the amplified measurement signal Sₐₘₚ supplied by amplifier 35 of detection system 10 for the first test. The instant t0, not visible in FIG. 21, corresponds to the sending of the synchronization signal Sync to control the current pulse generator 33, given that the duration between the rising edge of the synchronization signal Sync and the instant at which the current pulse is sent into the conductor wire 50 lasts from 1 ns to 100 ns, typically 6 ns. The peak magnitude is representative of the magnetic field B_{z} along the axis D of the tapered guide 40.

In the second test, the probe 20 shown in FIG. 1 is used. The height of the tapered guide 40, measured along its axis of revolution, is 40 mm and the diameter at the base 41 is 5.5 mm. The angle at the apex of tapered guide 40 is 7.8°. The lateral extent of tip 42 is approximately 150 μm. Conductor wire 50 has a diameter of 40 μm. The magnetic field of the permanent magnet has a magnitude of 480 mT. Two measurements are taken. The orientation of the magnet for the first measurement is the inverse of the orientation of the magnet for the second measurement.

FIG. 22 illustrates evolution curves C2_1 and C2_2 as a function of time of the amplified measurement signal Sₐₘₚ supplied by amplifier 35 of detection system 10 for the second test. Time t0 corresponds to the sending of the synchronization Sync signal to control current pulse generator 33. The orientation of the magnet for curve C2_1 is the inverse of the orientation of the magnet for curve C2_2. It can be seen that, depending on whether the north pole (curve C2_1) or the south pole (curve C2_1) of the permanent magnet is presented, the Lorentz magnetic force reverses and the phase of the signal supplied by the electroacoustic transducer 60, with a center frequency equal to 769 kHz in the second test, changes by 180°. In the second test, the tapered guide 40 introduces a delay of approximately 13 μs, sufficient to separate the spurious reception signal corresponding to the instant of the current pulse from the reception signal of the ultrasonic wave, the magnitude of which is proportional to the magnetic field B_{z}. In the second test, as the end 42 of the tapered guide 40 is almost point-like, the Lorentz force is exerted on a volume that is also almost point-like, and there is no acoustic resonance at the end to interfere with the waveform. The transmission of the Lorentz force in the form of stress carried by a source of low mechanical radiation impedance is therefore more efficient, and the electrical output signal is increased, compared with the truncated tip of the tapered guide 40 of the first test, by a factor of 2.4 (400 mV peak compared with 170 mV peak), but in general this factor can be greater than 10.

In the third and fourth tests, probe 20 and the permanent magnet from the second test are used. In the third and fourth tests, probe 20 is used in the reciprocal operating mode. Electroacoustic transducer 60 is excited by a 60 V voltage pulse with a duration of 270 ns.

FIG. 23 shows evolution curves C3_1 and C3_2 as a function of time of the amplified measurement signal Sₐₘₚ supplied by amplifier 35 of detection system 10 for the third test. Time t0 corresponds to the sending of the synchronization signal Sync to control current pulse generator 33. The orientation of the magnet for curve C3_1 is the inverse of the orientation of the magnet for curve C3_2. It can be seen that, depending on whether the north pole (curve C3_1) or the south pole (curve C3_1) of the permanent magnet is presented, the Lorentz magnetic force reverses and the phase of the electromotive force in conductor wire 50 changes by 180°.

FIG. 24 illustrates evolution curves C4_1 and C4_2 as a function of time of the amplified measurement signal Sₐₘₚ supplied by amplifier 35 of detection system 10 for the fourth test. Curve C4_1 is obtained in the presence of the permanent magnet, and curve C4_2 is obtained in the absence of the permanent magnet. In the presence of the permanent magnet, the output signal reaches 100 mV peak, i.e. between 3 and 4 times less than in the direct configuration. Curve C4_2 illustrates that no thermoacoustic effect is observed in the absence of the magnetic field B_{z} in the reciprocal operating mode.

In the fifth test, probe 20 and the permanent magnet from the second test are used. For the fifth test, probe 20 is used in direct operating mode.

FIG. 25 illustrates evolution curves C5_1 and C5_2 as a function of time for the amplified measurement signal Sₐₘₚ supplied by amplifier 35 of detection system 10 for the fourth test. Curve C5_1 is obtained in the presence of the permanent magnet and curve C5_2 is obtained in the absence of the permanent magnet. As shown in figure C4_2, in the direct operating mode, a thermoacoustic signal is observed, which is therefore characterized by the presence of an ultrasonic signal even when the magnetic field B_{z} to be measured is zero. However, the thermoacoustic effect reaches 80 mVc, whereas the magnetoacoustic signal in the presence of the magnetic field reaches 1.2 V, i.e. 15 times more than the thermoacoustic signal. The thermoacoustic signal therefore represents a noise level of around 32 mT. By recording the thermoacoustic signal and subtracting it from the measurement signal, the thermoacoustic noise can be reduced to less than 1 mT. This improves sensitivity to weak fields. Thermoacoustic noise decreases as the diameter of the conductor wire 50 increases.

In the sixth test, a first measurement is made using the probe 20 and permanent magnet from the second test, and a second measurement is made using the probe 20 from the second test and an electromagnet as the source of the magnetic field B_{z} to be measured. The electromagnet comprises nine turns of 2 mm diameter wire surrounding a ferrite core. For the sixth test, probe 20 is used in direct operating mode and the current pulse passing through conductor wire 50 has a duration Δt equal to 400 ns and an intensity I equal to 50 A. The magnetic field supplied by the permanent magnet has a magnitude of 450 mT.

FIG. 26 illustrates evolution curves C6_1 and C6_2 as a function of time of the electrical signal supplied by amplifier 35 of detection system 10 for the sixth test. Curve C6_1 is obtained when measuring the magnetic field emitted by the permanent magnet. Curve C6_2 is obtained when measuring the magnetic field emitted by the electromagnet. The electromagnet is driven for a pulse of 400 ns duration. The current pulse in conductor wire 50 is simultaneous with the current pulse in the electromagnet.

Various embodiments and variants have been described. Those skilled in the art will understand that certain features of these embodiments can be combined and other variants will readily occur to those skilled in the art. By way of example, the embodiment of the probe 20 described in connection with FIG. 6 comprising supports 83 and 84 can be implemented with the embodiments of the tapered guides 40 described in connection with FIGS. 2 to 5. Similarly, the embodiment of probe 20 described in relation to FIG. 7 comprising a shell 87 can be implemented with the embodiments of tapered guides 40 described in relation to FIGS. 2 to 5.

Finally, the practical implementation of the embodiments and variants described herein is within the capabilities of those skilled in the art based on the functional description provided hereinabove.

1. A device for detecting a magnetic field comprising:
a first tapered acoustic waveguide having a first base and a first tapered end;
a first electrically conductive wire rigidly coupled to the first tapered end; and
an electroacoustic transducer rigidly coupled to the first base.

2. The device according to claim 1, wherein the first tapered acoustic waveguide extends along an axis from the first base to the first tapered end, the cross-section of the first tapered acoustic waveguide decreasing from the first base to the first tapered end, and wherein the first electrically conductive wire comprises a portion orthogonal to said axis-(D) at the first tapered end.

3. The device according to claim 2, wherein the electroacoustic transducer is a transverse-wave electroacoustic transducer oriented in the direction of said portion.

4. The device according to claim 1, wherein the first tapered acoustic waveguide is shaped like a cone or truncated cone.

5. The device according to claim 4, wherein the first tapered acoustic waveguide has an apex angle of less than 15°.

6. The device according to claim 4, wherein the first tapered acoustic waveguide is shaped like a truncated cone, the first tapered end comprising a flat surface.

7. The device according to claim 6, wherein the flat surface has a diameter less than or equal to half a wavelength of the phase velocity of the bending waves in the first tapered end.

8. The device according to claim 6, wherein the flat surface has a radius of less than 1 mm.

9. The device according to any one of claims 6, wherein the first tapered acoustic waveguide comprises a notch in the flat surface receiving the first electrically conductive wire.

10. The device according to any one of claims 1, wherein the first tapered acoustic waveguide is shaped like a prism with a triangular base.

11. The device according to claim 10, wherein the first electrically conductive wire comprises an electrically conductive track deposited on the first tapered acoustic waveguide.

12. The device of claim 10, wherein the first electrically conductive wire comprises an electrically conductive blade extending along a flank of the first tapered acoustic waveguide away from said flank and connected to the first tapered end

13. The device according to claim 1, wherein the electroacoustic transducer is a piezoelectric transverse wave transducer or an electromagnetic transverse wave transducer.

14. The device according to claim 1, wherein the first tapered acoustic waveguide is made of a non-magnetic material.

15. The device according to claim 14, wherein the first tapered acoustic waveguide is made of a material selected from the group comprising glass, silicon, ceramics, non-magnetic metals, austenitic steel, and non-magnetic metal alloys.

16. The device according to claim 1, wherein the melting temperature of the first tapered acoustic waveguide and the melting temperature of the first electrically conductive wire are above 1000° C.

17. The device according to claim 1, comprising a support of electrically insulating material surrounding the first tapered acoustic waveguide midway between the first base and the first tapered end.

18. The device according to claim 1, comprising an electrically conductive shell surrounding the first tapered acoustic waveguide, at a distance from the tapered acoustic waveguide, and comprising an opening for the passage of the first tapered end.

19. The device according to claim 1, wherein the electroacoustic transducer comprises a second tapered acoustic waveguide comprising a second base and a second tapered end, a second electrically conductive wire rigidly coupled to the second tapered end, and a first permanent magnet facing the second tapered end.

20. The device according to claim 19, wherein the first tapered acoustic waveguide and the second tapered acoustic waveguide form a single-piece part.

21. The device according to claim 1, further comprising a third tapered acoustic waveguide rigidly coupled to the first tapered acoustic waveguide, the third tapered acoustic waveguide comprising a third base and a third tapered end, a third electrically conductive wire rigidly coupled to the third tapered end, and a second permanent magnet opposite the third tapered end, the electroacoustic transducer being located between the first base and the third base.

22. The device according to claim 21, wherein the electroacoustic transducer comprises two piezoelectric plates located opposite each other and operating in phase opposition.

23. A magnetic field measurement system comprising a device for detecting a magnetic field according to claim 1, and a control and acquisition device connected to the device for detecting a magnetic field comprising a generator configured to supply at least one current pulse in the first electrically conductive wire and an acquisition chain for detecting an electrical signal supplied by the electroacoustic transducer or a generator configured to supply at least one voltage pulse controlling the electroacoustic transducer, and an acquisition chain for detecting an electrical signal supplied by the first electrically conductive wire.

24. The system according to claim 23, wherein the magnetic field corresponds to a magnetic pulse, and wherein the control and acquisition device is configured so that the generator provides a current pulse in the first electrically conductive wire synchronous with the magnetic pulse.

25. The system according to claim 23, wherein the control and acquisition device comprises a module for controlling the generator configured to receive a binary synchronization signal and a signal representative of a time delay, and to control the generator to supply the current pulse or the voltage pulse at the end of the time delay after reception of the synchronization signal.

26. The system according to any one of claims 23, wherein the generator is configured to supply the current pulse having a duration half as short as the period corresponding to the frequency of maximum variation of the magnetic field.

27. The system according to any one of claims 23, wherein the control and acquisition device comprises an amplifier receiving the measurement signal, the gain of which is programmable in increasing steps, each step corresponding to a possible range of variation in the magnitude of the magnetic field to be measured.
